(19) United States
(12) Patent Application Publication
(10) Pub. No.: US 2025/0351267 A1
(43) Pub. Date: Nov. 13, 2025

(54) PET FILM PRESSING CCS ASSEMBLY

(71) Applicant: GUANGZHOU AMPHENOL SINCERE FLEX CIRCUITS CO., LTD, Guangzhou (CN)

(72) Inventors: Jiawen CHEN, Guangzhou (CN); Wei LI, Guangzhou (CN); Min YU, Guangzhou (CN); Gaixian SUN, Guangzhou (CN)

(73) Assignee: GUANGZHOU AMPHENOL SINCERE FLEX CIRCUITS CO., LTD, Guangzhou (CN)

(21) Appl. No.: 18/951,673

(22) Filed: Nov. 19, 2024

(30) Foreign Application Priority Data
May 7, 2024 (CN) 202420968932.4

(51) Int. Cl. H05K 1/03; C09J 7/24; H05K 1/05

(52) U.S. Cl. CPC H05K 1/0393; C09J 7/243; H05K 1/056; H05K 2201/0129; H05K 2201/0145

(57) ABSTRACT

A polyethylene terephthalate (PET) film pressing cell connection system (CCS) assembly is provided. The PET film pressing CCS assembly includes a PET film, where an upper surface of the PET film is provided with adhesive and adhered with two rows of aluminum foils; the upper surface of the PET film between the two rows of aluminum foils is adhered with a flexible printed circuit (FPC); two sides of the FPC are provided with protruding nickel sheets; the nickel sheets at the two sides of the FPC are welded to the two rows of aluminum foils, respectively; the FPC and the aluminum foils welded by the nickel sheets are adhered and fixed to the PET film through pressing; and the upper surface of the PET film is provided with a window corresponding to a bending groove of the aluminum foil.

### CROSS-REFERENCE TO THE RELATED APPLICATIONS

This application is based upon and claims priority to Chinese Patent Application No. 202420968932.4, filed on May 7, 2024, the entire contents of which are incorporated herein by reference.

### TECHNICAL FIELD

The present disclosure relates to a cell connection system (CCS), and in particular to a polyethylene terephthalate (PET) film pressing cell connection system (CCS) assembly.

### BACKGROUND

Due to the characteristics of battery cells, the temperature and charging/discharging current of a battery must be monitored in real time throughout battery operation in new energy power and automobiles. A cell connection system (CCS) assembly acquires temperature and current signals while connecting the cell.

The traditional CCS assembly mainly includes a circuit board and aluminum foils. The circuit board and aluminum foils are attached to an insulation film, which plays a protective and supporting function. There is a bending groove in the middle of the aluminum foil, and the bending groove can deform to prevent the aluminum foil from disconnecting from the pole of the battery cell due to thermal expansion and contraction. However, when the bending groove of the aluminum foil in the traditional CCS assembly deforms, it is easy to tear the protective and supporting insulation film and cause product damage.

### SUMMARY

An objective of the present disclosure is to provide a polyethylene terephthalate (PET) film pressing cell connection system (CCS) assembly, which can prevent a bending groove of an aluminum foil from tearing a PET film due to thermal expansion and contraction, thereby avoiding the risk of product damage.

In the present disclosure, the PET film pressing CCS assembly includes a PET film, where an upper surface of the PET film is provided with adhesive and adhered with two rows of aluminum foils; the upper surface of the PET film between the two rows of aluminum foils is adhered with a flexible printed circuit (FPC); two sides of the FPC are provided with protruding nickel sheets; the nickel sheets at the two sides of the FPC are welded to the two rows of aluminum foils, respectively; the FPC and the aluminum foils welded by the nickel sheets are adhered and fixed to the PET film through pressing; and the PET film is provided with a window corresponding to a bending groove of the aluminum foil.

In the PET film pressing CCS assembly of the present disclosure, the FPC and the aluminum foils welded by the nickel sheets are adhered and fixed to the PET film through pressing, and the PET film is provided with the window corresponding to the bending groove of the aluminum foil through pressing. The design can prevent the bending groove of the aluminum foil from tearing the PET film due to thermal expansion and contraction, thereby avoiding the risk of product damage. Due to the pre-applied adhesive on the upper surface of the PET film, the aluminum foils and FPC can be positioned on the PET film in an early stage of pressing, achieving convenient operation. In addition, the nickel sheets at the two sides of the FPC are welded integrally to the two rows of aluminum foils respectively and fixed to the PET film through pressing. In this way, the FPC and the aluminum foils are not easily offset, which improves the pressing effect and yield.

In a preferred solution of the present disclosure, the adhesive is AD adhesive.

In a preferred solution of the present disclosure, an exhaust hole penetrating upper and lower surfaces of the PET film is provided on the PET film between the two rows of aluminum foils.

In a preferred solution of the present disclosure, the FPC is a U-shaped FPC.

In a preferred solution of the present disclosure, the FPC is provided with a first thermistor and a second thermistor.

In a preferred solution of the present disclosure, the PET film is provided with a thermistor window formed through pressing and corresponding to the second thermistor.

In a preferred solution of the present disclosure, the FPC is provided with a glass fiber stiffener and aluminum stiffeners; the FPC on the glass fiber stiffener is provided with a connector; and the aluminum stiffeners are respectively located on backs of the first thermistor and the second thermistor.

### BRIEF DESCRIPTION OF THE DRAWINGS

FIG. 1 a back view of a PET film pressing CCS assembly according to the present disclosure;

FIG. 2 a front view of the PET film pressing CCS assembly according to the present disclosure; and

FIG. 3 is a structural diagram of a FPC according to the present disclosure.

### DETAILED DESCRIPTION OF THE EMBODIMENTS

The following clearly and completely describes the technical solutions in the embodiments of the present disclosure with reference to drawings. Apparently, the described embodiments are merely some rather than all of the embodiments of the present disclosure. All other embodiments obtained by those of ordinary skill in the art based on the embodiments of the present disclosure without creative efforts shall fall within the protection scope of the present disclosure.

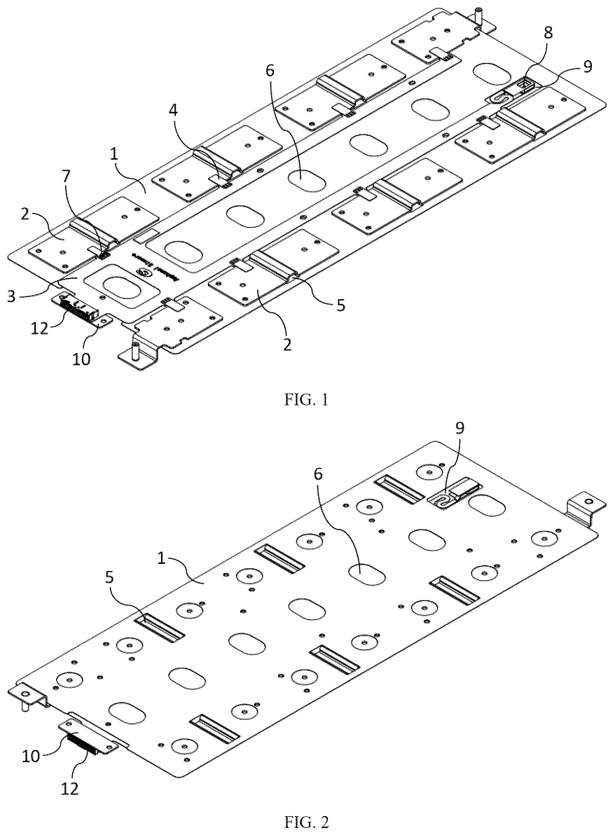

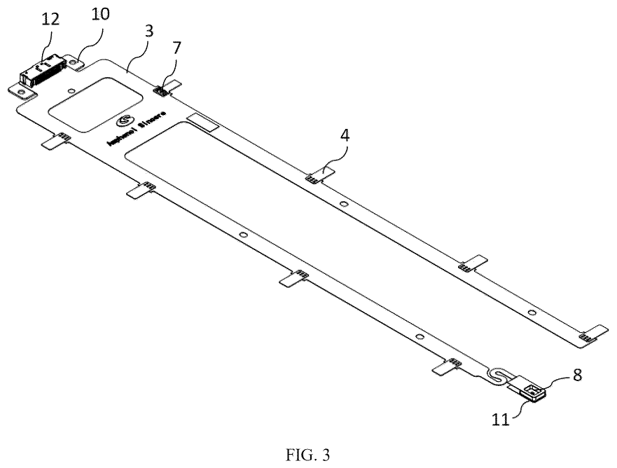

As shown in FIGS. 1 to 3, a PET film pressing CCS assembly includes PET film 1. An upper surface of the PET film is provided with adhesive and adhered with two rows of aluminum foils 2. The upper surface of the PET film between the two rows of aluminum foils is adhered with flexible printed circuit (FPC) 3. Two sides of the FPC are provided with protruding nickel sheets 4. The nickel sheets at the two sides of the FPC are welded to the two rows of aluminum foils, respectively. The FPC and the aluminum foils welded by the nickel sheets are adhered and fixed to the PET film through pressing. The PET film is provided with window 5 corresponding to the bending groove of the aluminum foil.

The FPC and the aluminum foils welded by the nickel sheets are adhered and fixed to the PET film through pressing, and the PET film is provided with the window corresponding to the bending groove of the aluminum foil through pressing. The design can prevent the bending groove of the aluminum foil from tearing the PET film due to thermal expansion and contraction, thereby avoiding the risk of product damage. Due to the pre-applied adhesive on the upper surface of the PET film, the aluminum foils and FPC can be positioned on the PET film in an early stage of pressing, achieving convenient operation. In addition, the nickel sheets at the two sides of the FPC are welded integrally to the two rows of aluminum foils respectively and fixed to the PET film through pressing. In this way, the FPC and the aluminum foils are not easily offset, which improves the pressing effect and yield.

In addition, the nickel sheet can include one end welded to the FPC and the other end tightly attached to the aluminum foil. The nickel sheet and the aluminum foil are fixed by laser welding to achieve electrical connection.

The lower surface of the PET film is coated with AD adhesive. The FPC is U-shaped with a hollow center, featuring small space occupation, low material usage, and low cost.

The FPC is provided with first thermistor 7 and second thermistor 8. The first thermistor and the second thermistor are configured to detect temperature changes on a battery pack in real time. The temperature change is converted into a resistance signal, and the resistance signal is transmitted to a battery management system (BMS) through a circuit and a connector on the FPC. In this way, real-time temperature of each battery module can be acquired. The FPC is provided with glass fiber stiffener 10 and aluminum stiffeners 11. The FPC on the glass fiber stiffener is provided with connector 12. The aluminum stiffeners are respectively located on backs of the first thermistor 7 and the second thermistor 8. The glass fiber stiffener 10 and the aluminum stiffeners 11 are 0.5 mm thick. The aluminum stiffeners 11 are provided with adhesive at one side and are adhered to the backs of the first thermistor 7 and the second thermistor 8, respectively. The design can prevent damage to the first thermistor 7 and the second thermistor 8 caused by thermal expansion and contraction, and prevent damage to the first thermistor 7 and the second thermistor 8 due to curling or bending of the FPC during transportation in a manufacturing process. In addition, the connector is located on the FPC, and the glass fiber stiffener offers support under the FPC. The connector is soldered onto a pad corresponding to the FPC and matched with a pre-designed connector on the BMS. That is, male and female terminals are connected correspondingly to complete information connection and transmission between the battery pack and the BMS. In addition, the PET film is provided with thermistor window 9 formed through pressing and corresponding to the second thermistor. The thermistor window 9 facilitates temperature detection of the second thermistor.

Exhaust hole 6 penetrating the upper and lower surfaces of the PET film is provided on the PET film between the two rows of aluminum foils. The exhaust hole 6 facilitates the exhaust of an expansion valve of the battery cell, improving the use safety of the CCS.

The detailed solutions of the present disclosure are illustrated through the above embodiments, but the present disclosure is not limited to the above detailed solutions, that is, it does not mean that the present disclosure must be implemented relying on the above detailed solutions. Those skilled in the art should understand that any improvement made to the present disclosure, any equivalent replacement of each raw material of the product of the present disclosure, any addition of auxiliary ingredients, and any selection of specific methods all fall within the protection and disclosure scope of the present disclosure.

What is claimed is:

1. A polyethylene terephthalate (PET) film pressing cell connection system (CCS) assembly, comprising a PET film, wherein an upper surface of the PET film is provided with adhesive and adhered with two rows of aluminum foils;
the upper surface of the PET film between the two rows of aluminum foils is adhered with a flexible printed circuit (FPC);
two sides of the FPC are provided with protruding nickel sheets;
the nickel sheets at the two sides of the FPC are welded to the two rows of aluminum foils, respectively;
the FPC and the aluminum foils welded by the nickel sheets are adhered and fixed to the PET film through pressing; and
the PET film is provided with a window corresponding to a bending groove of the aluminum foil.

2. The PET film pressing CCS assembly according to claim 1, wherein the adhesive is AD adhesive.

3. The PET film pressing CCS assembly according to claim 1, wherein an exhaust hole penetrating upper and lower surfaces of the PET film is provided on the PET film between the two rows of aluminum foils.

4. The PET film pressing CCS assembly according to claim 1, wherein the FPC is a U-shaped FPC.

5. The PET film pressing CCS assembly according to claim 1, wherein the FPC is provided with a first thermistor and a second thermistor.

6. The PET film pressing CCS assembly according to claim 5, wherein the PET film is provided with a thermistor window formed through pressing and corresponding to the second thermistor.

7. The PET film pressing CCS assembly according to claim 5, wherein the FPC is provided with a glass fiber stiffener and aluminum stiffeners; the FPC on the glass fiber stiffener is provided with a connector; and the aluminum stiffeners are respectively located on backs of the first thermistor and the second thermistor.
